(19) United States
(12) Patent Application Publication
(10) Pub. No.: US 2016/0314983 A1
(43) Pub. Date: Oct. 27, 2016

(54) METHOD OF FORMING PATTERNS OF A SEMICONDUCTOR DEVICE

(71) Applicant: SAMSUNG ELECTRONICS CO., LTD., Suwon-Si (KR)

(72) Inventors: Eun-Shoo HAN, Hwaseong-Si (KR); Dong-Kwon KIM, Seoul (KR); Bong-Cheol KIM, Seoul (KR); Kang-ILL SEO, Chungcheongbuk-Do (KR)

(21) Appl. No.: 14/693,668

(22) Filed: Apr. 22, 2015

(51) Int. Cl. H01L 21/308; H01L 21/8234

(52) U.S. Cl. CPC H01L 21/3086; H01L 21/3081; H01L 21/823431

(57) ABSTRACT

A method of forming patterns of a semiconductor device includes sequentially forming first to third mask layers on a substrate including a first region and a second region, etching the third mask layer formed in the first region to form first mask elements of a first mask pattern, etching the third mask layer formed in the second region to form second mask elements of a second mask pattern, forming a first spacer film covering the second mask elements, forming a second spacer film on the first spacer film to fully fill at least one trench between the second mask elements and on the first mask elements, removing portions of the first and second spacer films to expose the upper surfaces of the first and second mask elements, etching the second mask layer, etching the first mask layer, and etching the substrate.

### TECHNICAL FIELD

The inventive concept of this disclosure relates to a method of forming patterns of a semiconductor device.

### DISCUSSION OF THE RELATED ART

Recently, semiconductor devices are being developed to operate at high speeds and low voltage. Semiconductor device fabrication processes are being developed to increase the degree of integration. Thus, patterns of highly scaled high integration semiconductor devices may be formed to have small widths and spaced apart from each other by short pitches.

Technological advances have also created a need for patterns of high integration semiconductor devices having various pitches.

### SUMMARY

An exemplary embodiment of the inventive concept provides a method of forming patterns of a semiconductor device, wherein the patterns of the semiconductor device have various pitches.

An exemplary embodiment of the inventive concept provides a method of forming patterns of a semiconductor device, wherein the patterns of the semiconductor device have small widths and various pitches.

The inventive concept is not limited to the exemplary embodiments set forth above. The inventive concept, as described below, may be embodied in numerous exemplary embodiments not described herein.

In an exemplary embodiment of the inventive concept, a method of forming patterns of a semiconductor device includes sequentially forming first to third mask layers on a substrate, wherein the substrate includes a first region and a second region, etching the third mask layer formed in the first region to form a first mask pattern, wherein the first mask pattern includes a plurality of first mask elements, and etching the third mask layer formed in the second region to form a second mask pattern, wherein the second mask pattern includes a plurality of second mask elements, forming a first spacer film, wherein the first spacer film covers the second mask elements of the second mask pattern and wherein the first spacer film is not formed in the first region, forming a second spacer film, the second spacer film being disposed on the first spacer film to fully fill at least one trench between the second mask elements of the second mask pattern and being disposed on the first mask elements of the first mask pattern, removing portions of the first and second spacer films covering upper surfaces of the first and second mask elements of the first and second mask patterns to expose the upper surfaces of the first and second mask elements of the first and second mask patterns, etching the second mask layer to form a third mask pattern, wherein the third mask pattern includes a plurality of third mask elements, etching the first mask layer using the third mask elements of the third mask pattern to form a fourth mask pattern, wherein the fourth mask pattern includes a plurality of fourth mask elements, and etching the substrate using the fourth mask elements of the fourth mask pattern.

In an exemplary embodiment of the inventive concept, forming the first spacer film includes fully covering at least one trench between the second mask elements of the second mask pattern.

In an exemplary embodiment of the inventive concept, the first mask layer includes two layers.

In an exemplary embodiment of the inventive concept, forming the first spacer film includes forming the first spacer film covering the first mask elements of the first mask pattern and the second mask elements of the second mask pattern, forming a block mask layer in the second region to at least partially cover the first spacer film, and removing the first spacer film disposed in the first region.

In an exemplary embodiment of the inventive concept, a first distance between neighboring second mask elements of the second mask pattern is equal to or less than double a sum of a thickness of the first spacer film and a thickness of the second spacer film.

In an exemplary embodiment of the inventive concept, a first pitch of a first mask element, from among the plurality of first mask elements of the first mask pattern, and a second pitch of a second mask element, from among the plurality of the second mask elements of the second mask pattern, are equal.

In an exemplary embodiment of the inventive concept, a first mask element, from among the plurality of first mask elements of the first mask pattern, has a first width, and a second mask element, from among the plurality of second mask elements of the second mask pattern, has a second width, and wherein the first width and the second width are not equal.

In an exemplary embodiment of the inventive concept, a thickness of the first spacer film is greater than a thickness of the second spacer film.

In an exemplary embodiment of the inventive concept, etching the substrate comprises forming a plurality of fins, wherein a first distance between neighboring fins from among the plurality of fins formed in the first region is shorter than a second distance between neighboring fins from among the plurality of fins formed in the second region.

In an exemplary embodiment of the inventive concept, a method of forming patterns of a semiconductor device includes forming a mask layer on a target layer, wherein the target layer includes a first region and a second region, etching the mask layer formed in the first region to form a first mask pattern, wherein the first mask pattern includes a plurality of first mask elements, wherein at least one first mask element of the first mask pattern has a first width, and wherein the at least one first mask element of the first mask pattern is spaced apart from a proximate first mask element of the first mask pattern by a first distance, etching the mask layer formed in the second region to form a second mask pattern, wherein the second mask pattern includes a plurality of second mask elements, wherein at least one second mask element has a second width, wherein the second width and the first width are not equal, and wherein the at least one second mask element of the second mask pattern is spaced apart from a proximate second mask element of the second mask pattern by a second distance, forming a first spacer film, wherein the first spacer film covers the second mask elements of the second mask pattern, and wherein the first spacer films is not formed in the first region, forming a second spacer film, wherein the second spacer film is disposed on the first spacer film to fully fill at least one trench between the second mask elements of the second mask pattern, and wherein the second spacer film covers the first mask elements of the first mask pattern, removing portions of the first and second spacer films covering upper surfaces of the first and second mask elements of the first and second mask patterns to expose the upper surfaces of the first and second mask elements of the first and second mask patterns, and etching the target layer.

In an exemplary embodiment of the inventive concept, a thickness of the first spacer film is greater than a thickness of the second spacer film.

In an exemplary embodiment of the inventive concept, the second distance between the at least one second mask element of the second mask pattern and the proximate second mask element of the second mask pattern is equal to or less than double a sum of a thickness of the first spacer film and a thickness of the second spacer film.

In an exemplary embodiment of the inventive concept, a first pitch of a first mask element, from among the plurality of first mask elements of the first mask pattern, and a second pitch of a second mask element, from among the plurality of second mask elements of the second mask pattern, are equal.

In an exemplary embodiment of the inventive concept, a method of forming patterns of a semiconductor device includes sequentially forming first to third mask layers on a substrate, wherein the substrate includes a first region and a second region, etching the third mask layer formed in the first region to form a first mask pattern, wherein the first mask pattern includes a plurality of first mask elements, and etching the third mask layer formed in the second region to form a second mask pattern, wherein the second mask pattern includes a plurality of second mask elements, forming a first spacer film, wherein the first spacer film covers the second mask elements of the second mask pattern and wherein the first spacer film is not formed in the first region, forming a second spacer film, wherein the second spacer film is disposed on the first spacer film, wherein the second spacer film fully fills at least one trench between the second mask elements of the second mask pattern, wherein the second spacer film is disposed on the first mask elements of the first mask pattern, removing portions of the first spacer film and portions of the second spacer film to expose upper surfaces of the first mask elements of the first mask pattern and upper surfaces of the second mask elements of the second mask pattern, etching the second mask layer to form a third mask pattern, wherein the third mask pattern includes a plurality of third mask elements, forming a third spacer film, wherein the third spacer film covers the third mask elements of the third mask pattern, removing portions of the third spacer film to expose upper surfaces of the third mask elements of the third mask pattern, etching the first mask layer to form a fourth mask pattern, wherein the fourth mask pattern includes a plurality of fourth mask elements, and etching the substrate to form a plurality of fins.

In an exemplary embodiment of the inventive concept, at least one distance between adjacent second mask elements of the second mask pattern is equal to or less than double a sum of a thickness of the first spacer film and a thickness of the second spacer film.

In an exemplary embodiment of the inventive concept, at least one pitch of a fin formed in the first region is different from at least one pitch of a fin formed in the second region.

In an exemplary embodiment of the inventive concept, forming the first spacer film comprises fully covering at least one trench between the second mask elements of the second mask pattern.

In an exemplary embodiment of the inventive concept, the first mask layer comprises two layers.

In an exemplary embodiment of the inventive concept, forming the first spacer film comprises forming the first spacer film covering the first mask elements of the first mask pattern and the second mask elements of the second mask pattern, forming a block mask layer in the second region to cover the first spacer film, and removing the first spacer film disposed in the first region.

In an exemplary embodiment of the inventive concept, a thickness of the first spacer film is greater than a thickness of the second spacer film.

In an exemplary embodiment of the inventive concept, a first mask element, from among the plurality of first mask elements of the first mask pattern, has a first width, and a second mask element, from among the plurality of second mask elements of the second mask pattern has a second width, and wherein the first width and the second width are not equal.

In an exemplary embodiment of the inventive concept, a first pitch of a first fin, from among the plurality of fins in the first region, is equal to a second pitch of a second fin, from among the plurality of fins in the second region.

### BRIEF DESCRIPTION OF THE DRAWINGS

The inventive concept will become more apparent by describing in detail exemplary embodiments thereof with reference to the attached drawings in which:

FIG. 1 to FIG. 18 are cross-sectional views illustrating a method of forming patterns of a semiconductor device according to an exemplary embodiment of the inventive concept.

FIG. 19 to FIG. 22 are cross-sectional views illustrating a method of forming patterns of a semiconductor device according to an exemplary embodiment of the inventive concept.

FIG. 23 is a block diagram of an electronic system including a semiconductor device fabricated according to a method of forming patterns of a semiconductor device according to an exemplary embodiment of the inventive concept.

FIG. 24 to FIG. 26 illustrate an exemplary semiconductor system which may incorporate a semiconductor device fabricated in accordance with a method of forming patterns of a semiconductor device according to an embodiment of the inventive concept.

### DETAILED DESCRIPTION OF THE EMBODIMENTS

The inventive concept and methods of accomplishing the same may be understood more readily by reference to the following description of exemplary embodiments and the accompanying drawings. The inventive concept may, however, include numerous exemplary embodiments thereof. Therefore, the inventive concept should not be construed as being limited to the exemplary embodiments described herein. Exemplary embodiments of the inventive concept are provided so that this disclosure may convey the inventive concept to those skilled in the art. Like reference numerals refer to like elements throughout the specification.

As used herein, the singular forms “a,” “an,” and “the” are intended to include the plural forms as well, unless the context clearly indicates otherwise.

It will be understood that when an element or layer is referred to as being “on,” “connected to” or “coupled to” another element or layer, it can be directly on, connected or coupled to the other element or layer, or intervening elements or layers may be present. In contrast, when an element is referred to as being “directly on,” “directly connected to,” or “directly coupled to” another element or layer, there are no intervening elements or layers present. As used herein, the term “and/or” includes any and all combinations of one or more of the associated listed items.

It will be understood that, although the terms first, second, or the like, may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the inventive concept.

Spatially relative terms such as “beneath,” “below,” “lower,” “above,” “upper” and the like may be used herein for ease of description to describe one element or feature's relationship to another element(s) or feature(s) as illustrated in the figures. It will be understood that the spatially relative terms are intended to encompass different orientations of a device in use or operation in addition to the orientation depicted in the figures. For example, if a device in a figure is turned over, elements described as “below” or “beneath” other elements or features would then be oriented “above” the other elements or features. Thus, the term “below” may encompass both an orientation of above and below. The device may be otherwise oriented (e.g., rotated 90 degrees or at other orientations) and the spatially relative descriptors used herein may be interpreted accordingly.

Exemplary embodiments of the inventive concept are described herein with reference to cross-section illustrations that are schematic illustrations of idealized exemplary embodiments. As such, variations from the shapes of the illustrations as a result of, for example, manufacturing techniques and/or tolerances, may be expected. Thus, the exemplary embodiments of the inventive concept should not be construed as limited to the particular shapes of regions illustrated herein but may include deviations in shapes that result from, for example, manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Accordingly, the regions illustrated in the figures are schematic in nature and their shapes are not intended to illustrate the actual shape of a region of a device and are not intended to limit the scope of the inventive concept.

It will be understood that terms such as those defined in commonly used dictionaries should be interpreted as having a meaning that is consistent with their meaning in the context of the relevant art and this specification and will not be interpreted in an idealized or overly formal sense unless expressly so defined herein.

A method of forming patterns of a semiconductor device according to an exemplary embodiment of the inventive concept will be described.

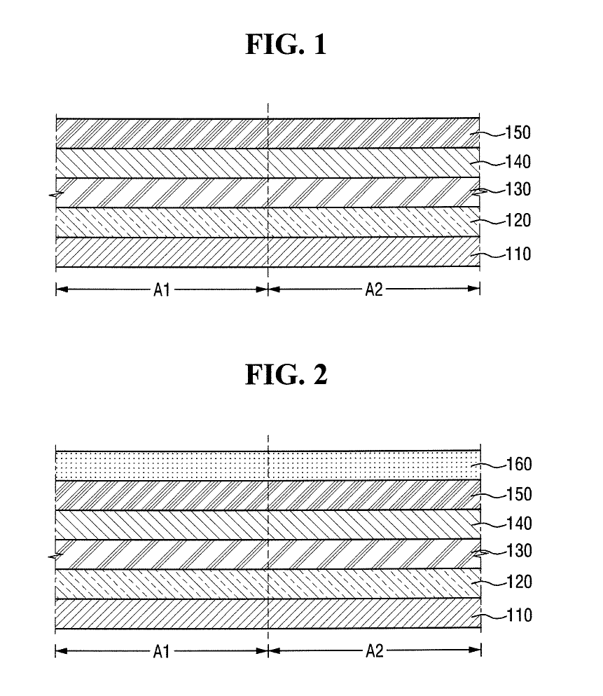

FIG. 1 to FIG. 18 are cross-sectional views illustrating a method of forming patterns of a semiconductor device according to an exemplary embodiment of the inventive concept.

Referring to FIG. 1, a first mask layer 120, a first barrier layer 130, a second mask layer 140, and a second barrier layer 150 are sequentially formed on a substrate 110.

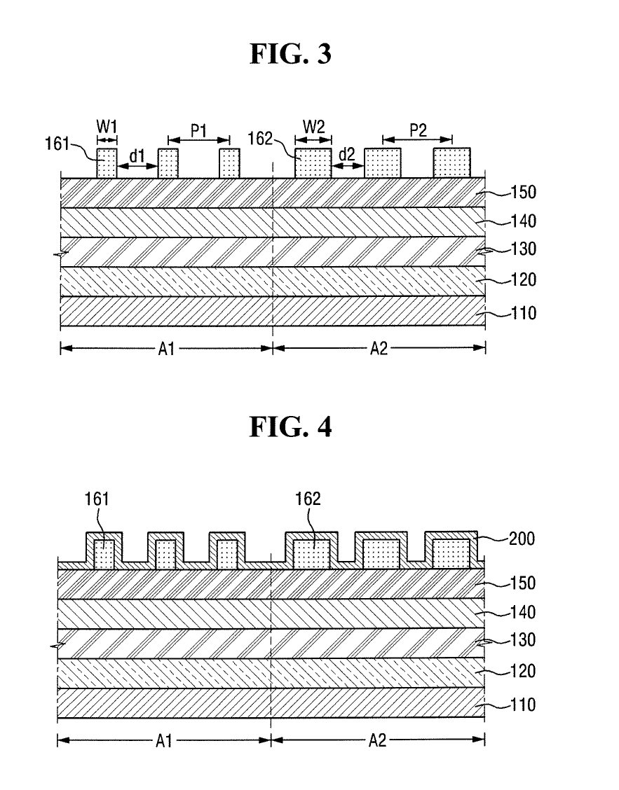

The substrate 110 may include a first region A1 and a second region A2. The first region A1 may be defined as a region in which a first mask pattern (reference numeral 161 of FIG. 3), that will be described later, may be formed, and the second region A2 may be defined as a region in which a second mask pattern (reference numeral 162 of FIG. 3), that will be discussed later, may be formed.

The substrate 110 may include a semiconductor material. The substrate 110 may include at least one of Si, Ge, SiGe, GaP, GaAs, SiC, SiGeC, InAs and InP. In an exemplary embodiment of the inventive concept, the substrate 110 may include a semiconductor material. However, the inventive concept is not limited thereto. Exemplary embodiments of the inventive concept, for example, may include a substrate 100 including any material that may form a small pattern through etching.

An etching target layer may be formed on the substrate 110. However, the etching target layer may not be formed on the substrate 110 if the substrate 110 is an etched object. Accordingly, the substrate 110 may serve as an etching target layer in some circumstances.

The first mask layer 120 may be formed on the substrate 110. The first mask layer 120 may include a material that has an etch selectivity relative to the substrate 110. For example, the first mask layer 120 may include a material that is minimally etched when etching the substrate 110. Thus, the first mask layer 120 may be patterned according to a process described below and may be formed as an etching mask for etching the substrate 110.

The first mask layer 120 may be a hard mask layer and may include either a nitride film (Si₃N₄) or an oxide film (SiO₂). However, the inventive concept is not limited thereto. The first mask layer 120 is shown as a singular layer in the drawings but the inventive concept is not limited thereto. According to an exemplary embodiment of the inventive concept, the first mask layer 120 may be formed, for example, by fixing together two or more layers.

The first mask layer 120 may be formed through a deposition process such as plasma enhanced chemical vapor deposition (PE-CVD). The first mask layer 120 may be formed using a silicon-based spin-on hard mask (Si—SOH) such as spin-on glass (SOG). An antireflective layer may be formed on the first mask layer 120. The antireflective layer may be formed through a chemical vapor deposition (CVD) process or other suitable processes using silicon oxynitride (SiON).

The first barrier layer 130 may be formed on the first mask layer 120. The first barrier layer 130 may be etched together with the first mask layer 120 in the etching process discussed below. For example, the first barrier layer 130 may have an etch selectivity similar to that of the first mask layer 120. The first barrier layer 130 may include a material having a high dielectric constant (high-k). However, the inventive concept is not limited thereto.

The second mask layer 140 may be formed on the first barrier layer 130. The second mask layer 140 may be used as a sacrificial layer for the application of quadruple patterning technology (QPT), however, the inventive concept is not limited thereto. The second mask layer 140 may be a hard mask layer substantially identical to the first mask layer 120. For example, the second mask layer 140 may include either an amorphous-carbon film or a metal film, but it is not limited thereto. In an exemplary embodiment of the inventive concept, the second mask layer 140 includes an amorphous-carbon film and may be formed, for example, by a spin coating process and a bake process. For example, an organic compound layer may be formed on the first barrier layer 130 by the spin coating process and the organic compound layer may be cured by the bake process, forming the second mask layer 140.

The second barrier layer 150 may be formed on the second mask layer 140. The second barrier layer 150 may be etched together with the second mask layer 140 in an etching process below. For example, the second barrier layer 150 may have an etch selectivity similar to that of the second mask layer 140. The second barrier layer 150 may include a material having a high dielectric constant (high-k), but the inventive concept is not limited thereto.

Referring to FIG. 2, a third mask layer 160 is formed on the second barrier layer 150. The third mask layer 160 may include a material identical to a material included in the second mask layer 140 and may be formed by a method substantially similar to the method described above for forming the second mask layer 140. For example, the second mask layer 140 and the third mask layer 160 may be used as sacrificial layers for the application of the QPT but the inventive concept is not limited thereto.

According to an exemplary embodiment of the inventive concept, patterns of a semiconductor device may have various pitches formed by a process employing the QPT. The QPT may in some embodiments include a double patterning technology (DPT). The QPT forms small patterns of a high integration semiconductor device, for example, having a size of several tens of nanometers.

Patterns formed using the QPT may have smaller widths and pitches than patterns formed through a conventional process. As a result, it may be difficult to control a pitch between patterns formed through the process. For example, there may be difficulties with an accurate overlay of mask patterning for removing pitches, in a specific region, when performing a fin cut process for controlling pitches of patterns. As the pitch between the patterns becomes smaller, the margin of the process becomes smaller.

According to an exemplary embodiment of the inventive concept, a method of forming patterns of a semiconductor device may eliminate the need for the fin cut process, or similar processes, for adjusting a distance between the patterns that have already been formed. According to an exemplary embodiment of the inventive concept, patterns having various pitches may be formed according to a method of forming patterns of a semiconductor device that employs the QPT.

The above description of the process employing the QPT is an example that illustrates an exemplary embodiment of the inventive concept. However, the inventive concept is not limited thereto. For example, the inventive concept may be exemplarily embodied in a patterning process that does not use the process employing the QPT.

Referring to FIG. 3, the third mask layer 160 may be patterned to form a first mask pattern 161 and a second mask pattern 162. The first mask pattern 161 and the second mask pattern 162 may be formed by forming a photoresist pattern on the third mask layer 160 and etching the third mask pattern 160 using the photoresist pattern as an etching mask.

The first mask pattern 161 may be formed in the first region A1 and the second mask pattern 162 may be formed in the second region A2. The first mask pattern 161 may include a plurality of first mask elements, and the second mask pattern 162 may include a plurality of second mask elements. According to an exemplary embodiment of the inventive concept, each of the first mask pattern 161 and the second mask pattern 162 includes three mask elements as shown in FIG. 3. However, the inventive concept is not limited thereto. For example, according to an exemplary embodiment of the inventive concept, each of the first mask pattern 161 and the second mask pattern 162 may include three or more mask elements.

A first mask element of the first mask pattern 161 may have a first width w1 and may have a first distance d1 and a first pitch p1 between the first mask element and a neighboring first mask element. In the second mask pattern 162, a second mask element may have a second width w2 and may have a second distance d2 and a second pitch p2 between the second mask element and a neighboring second mask element. The widths, pitches, or distances of the first and second mask elements may be all the same, may be partially the same, or may be all different from each other.

In an exemplary embodiment of the inventive concept, the first pitch p1 and the second pitch p2 are substantially equal. However, the inventive concept is not limited thereto. For example, the first pitch p1 and the second pitch p2 may be different from each other.

Although, in FIG. 3, the first width w1 is shown to be smaller than the second width w2 and the first distance d1 is shown to be greater than the second distance d2, the inventive concept is not limited thereto. For example, the pitches, widths, and distances of the first and second mask elements of the first and second mask patterns 161 and 162 may all be different.

Referring to FIG. 4, a first spacer film 200 may cover the first and second mask patterns 161 and 162, respectively, in the first and second regions A1 and A2, respectively. According to an exemplary embodiment of the inventive concept, the first spacer film 200 may be conformal along the first and second mask elements of the first and second mask patterns 161 and 162. For example, the first spacer film 200 may cover upper surfaces and side walls of the first and second mask elements included in each of the first and second mask patterns 161 and 162. According to an exemplary embodiment of the inventive concept, the first spacer film 200 may fill trenches between the first mask elements of the first mask pattern 161 and may fill trenches between the second mask elements of the second mask pattern 162.

The first spacer film 200 may include a material having an etch selectivity relative to the first and second elements of the first and second mask patterns 161 and 162. The first spacer film 200 may include a mid-temperature oxide (MTO), a high-temperature oxide (HTO) or a silicon oxide such as an atomic layer deposition (ALD) oxide. However, the inventive concept is not limited thereto.

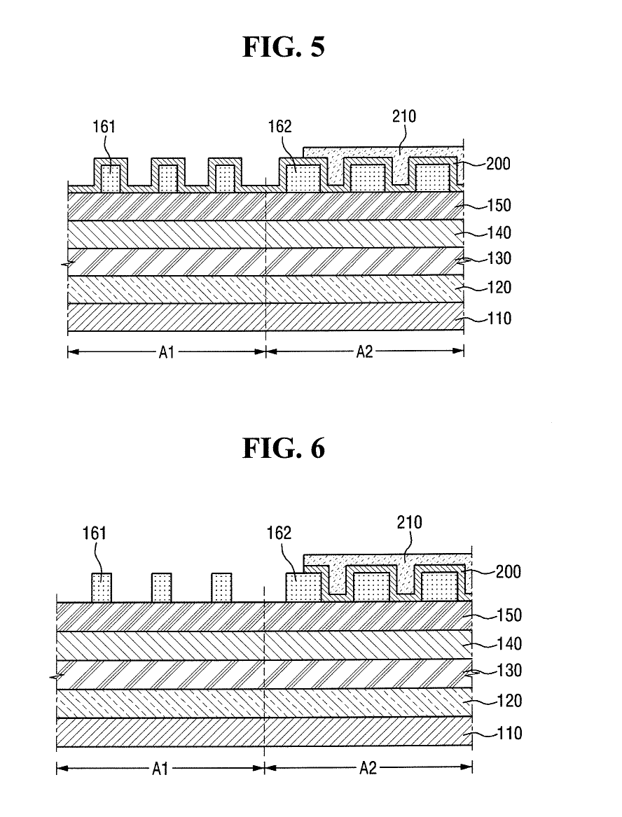

Referring to FIG. 5, a block mask layer 210 covers the first spacer film 200 in the second region A2. The block mask layer 210 covering the first spacer film 200 may be disposed on the second mask pattern 162. As shown in FIG. 5, the block mask layer 210 may cover only a portion of one of the second mask elements of the second mask pattern 162 in an end portion of the second region A2. However, the inventive concept is not limited thereto. For example, according to an exemplary embodiment of the inventive concept, the block mask layer 210 may cover the second mask elements of the second mask pattern 162 in their entirety.

The block mask layer 210 may include, for example, either an amorphous-carbon block or a photoresist block, but it is not limited thereto.

Referring to FIG. 6, the first spacer film 200 disposed in the first region A1 may be removed. A portion of first spacer film 200 on which the block mask layer 210 is formed may not be removed. A portion of the first spacer film 200 on which the block mask layer 210 is not formed may be removed.

For example, a portion of the first spacer film 200 in a region on which the block mask layer 210 is not formed may be removed using an etch selectivity between the block mask layer 210 and the first spacer film 200 through an etching process such as wet or plasma etching.

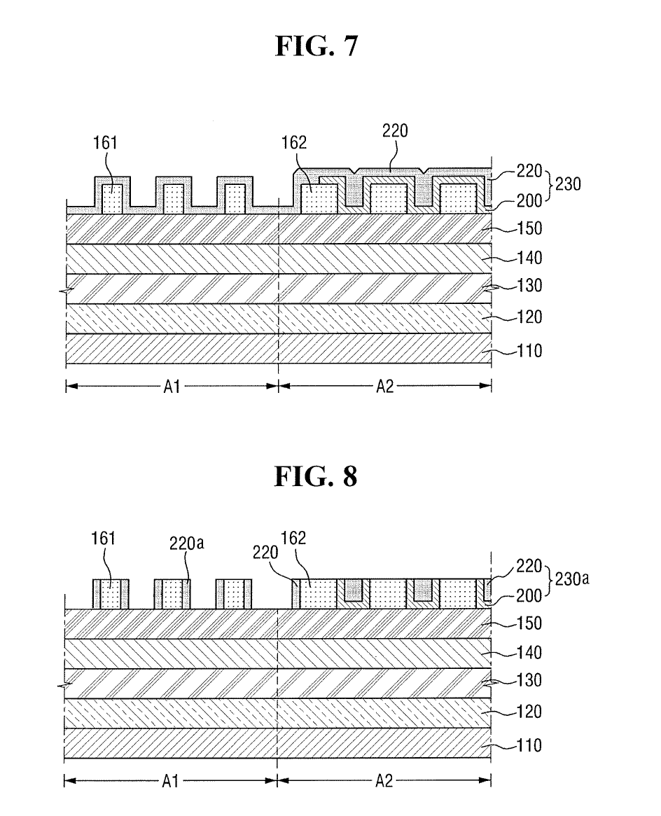

Referring to FIG. 7, after removal of the block mask layer 210, a second spacer film 220 may cover the first region A1 and the second region A2. For example, the second spacer film 220 may cover the first mask elements of the first mask pattern 161 disposed in the first region A1, and the first spacer film 200 disposed in the second region A2.

The block mask layer 210 may be removed by an ashing process or a strip process.

A portion of the second spacer film 220 may overlap the first spacer film 200 in the second region A2. The first spacer film 200 and the second spacer film 220 may be coupled with each other to form a coupled spacer film 230.

The second spacer film 220 may fully fill the each of a plurality of trenches between the second mask elements of the second mask pattern 162.

In an exemplary embodiment of the inventive concept, a single-layered spacer film may be formed in the first region A1. A double-layered spacer film may be formed in the second region A2. A trench between neighboring first mask elements of the first mask pattern 161 disposed in the first region A1 may not be fully filled by the single-layered spacer film. However, a trench between neighboring second mask elements of the second mask pattern 162 may be fully filled by the double-layered spacer film. Accordingly, the thickness of the double-layered spacer film is larger than the thickness of the single-layered spacer film.

In an exemplary embodiment of the inventive concept, to fully fill trenches between neighboring second mask elements of the second mask pattern 162, disposed in the second region A2, with the first and second spacer films 200 and 220, each of the second distances d2, between the neighboring second mask elements of the second mask pattern 162 may be equal to or less than a sum, of a thickness of the first spacer film 200 and a thickness of the second spacer film 220, multiplied by two. For example, to enable the second spacer film 220 to fully fill trenches between the neighboring second mask elements of the second mask pattern 162, a spatial relationship may exist between the second distances d2, the thickness of first spacer film 200, and thickness of the second spacer film 220.

Referring to FIG. 8, portions of the first spacer film 200 and portions of the second spacer film 220 may be removed. The removal of the portions of the first and second spacer films 200 and 220 may be performed by an etchback process. In the first region A1, the etchback process may include removing the second spacer film from upper surfaces of the first mask elements of the first mask pattern 161 and from upper surface portions of the second mask layer 150 to expose the upper surfaces of the first mask elements of the first mask pattern 161 and the upper surface portions of the second mask layer 150. In the second region A2, the etchback process may include removing the first and second spacer films 200 and 220 from upper surfaces of the second mask elements of the second mask pattern 162. As a result of the etchback process, a plurality of first spacers 220a and a plurality of second spacers 230a may be formed. The first spacers 220a may be arranged in the first region A1 and the second spacers 230a may be arranged in the second region A2.

The first spacers 220a may be formed only as a result of the etchback process performed on the second spacer film 220. The second spacers 230a may be formed as a result of the etchback process performed on the coupled spacer film 230, in which the first spacer film 200 and the second spacer film 220 are coupled with each other.

In an embodiment of the inventive concept, the first spacers 220a may be formed on the side walls of the first mask elements of the first mask pattern 161, in the first region A1. Thus, trenches between neighboring first mask elements of the first mask pattern 161 may be partially filled. On the other hand, trenches between neighboring second mask elements of the second mask pattern 162, in the second region A2, may be fully filled by the second spacers 230a. A width of a first spacer 220a and a width of a second spacer 230a may be different from each other. However, the inventive concept is not limited thereto. For example, in an exemplary embodiment of the inventive concept, a first spacer 220a and a second spacer 230a may have equal widths.

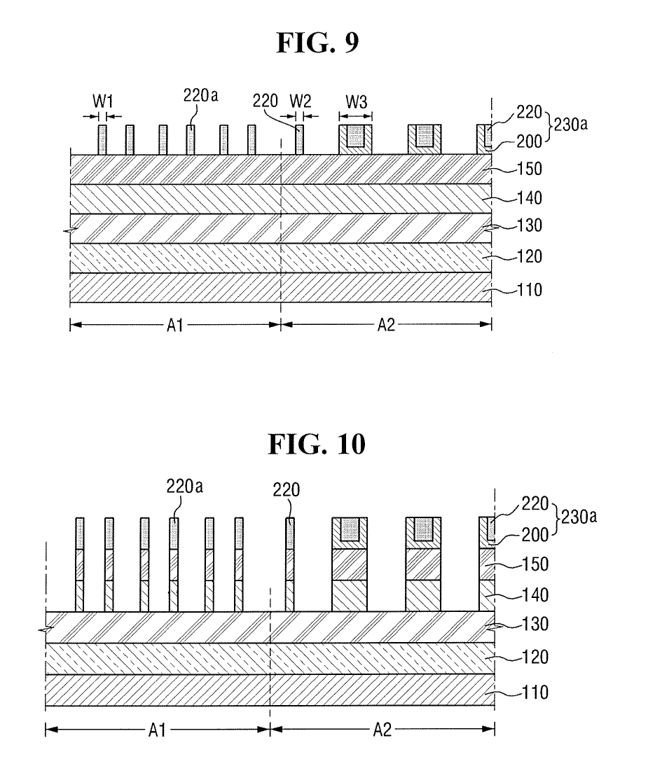

Referring to FIG. 9, the first and second elements of the first and second mask patterns 161 and 162 are removed. The first and second spacers 220a and 230a may be materials having an etch selectivity relative to the first and second mask patterns 161 and 162. Thus, an etchant that etches the first mask elements of the first mask pattern 161 and the second mask elements of the second mask pattern 162, but does not etch the first and second spacers 220a and 230a, may be used to remove the first and second mask elements of the first and second mask patterns 161 and 162.

In an exemplary embodiment of the inventive concept, a plurality of first spacers 220a may be formed in a first region A1 through a process of removing the first mask elements of the first mask pattern 161, wherein each of the first spacers 220a from among the plurality of the first spacers 220a has a first width w1. A plurality of second spacers 230a may be formed in a second region A2, wherein some of the second spacers 230a from among the plurality of second spacers 230a have a second width w2, and at least one of the second spacers 230a from the plurality of second spacers 230a has third width w3, wherein the second width w2 and the third width w3 may be different from each other. However, the first width w1 of a first spacer 220a and the second width w2 of a second spacer 230a may be equal. In an exemplary embodiment of the inventive concept, a second spacer 230a having a second width w2, which may be different from a third width w3 of a neighboring second spacer 230a, may be formed in an end portion of a second region A2. However, the inventive concept is not limited thereto. For example, according to an exemplary embodiment of the inventive concept, spacers having the same width or spacers having different widths may be formed in the second region A2 through a variation of process conditions, mask patterns, etc.

Referring to FIG. 10, the second barrier layer 150 and the second mask layer 140 are sequentially and partially removed. For example, the second barrier layer 150 and the second mask layer 140 may be sequentially and partially removed by an etching process, using the first and second spacers 220a and 230a as masks.

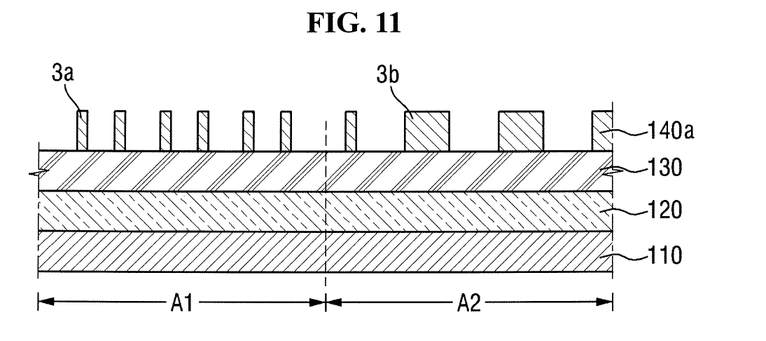

Referring to FIG. 11, the second barrier layer 150 and the first and second spacers 220a and 230a disposed on the second mask 140 are removed to form a third mask pattern 140a.

The third mask pattern 140a may include a plurality of third mask pattern elements 3a disposed in the first region A1 and a plurality of third mask pattern elements 3b disposed in the second region A2. As shown in FIG. 11, the third mask pattern elements of the third mask pattern 140a may have different widths depending on the region in which the third mask pattern elements are formed. In an exemplary embodiment of the inventive concept, the third mask pattern elements of the third mask pattern 140a having the same width may be concentrated in a specific region of the substrate. However, the inventive concept is not limited thereto. For example, according to an exemplary embodiment of the inventive concept, third mask pattern elements of the third mask pattern 140a having different widths may be formed alternately with each other in the same region of the substrate.

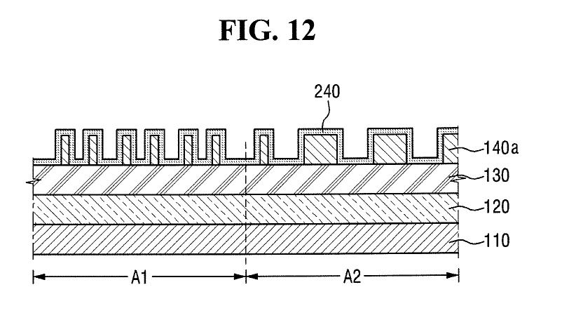

Referring to FIG. 12, a third spacer film 240 may cover the third mask elements of the third mask pattern 140a. According to an exemplary embodiment of the inventive concept, the third spacer film 240 may be conformal along the third mask elements of the third mask pattern 140a. For example, the third spacer film 240 may be formed along the upper surfaces and side walls of the third mask pattern elements of the third mask pattern 140a.

The properties of the third spacer film 240 may be identical to the properties of first spacer film 200 or the second spacer film 220, as described above. Therefore a detailed description of the properties of the third spacer film 240 will be omitted for brevity.

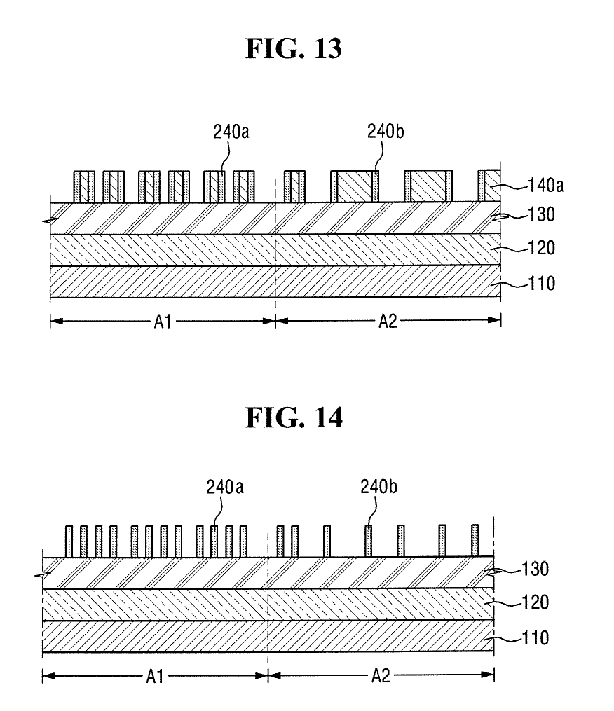

Referring to FIG. 13 and FIG. 14, a plurality of third spacers 240a and a plurality of third spacers 240b may be formed using the etchback process. For example, portions of the third spacer film 240 may be removed to expose the upper surfaces of the third mask elements of the third mask pattern 140a and upper surface portions of the first barrier layer 130. The third spacers 240a and the third spacers 240b may be formed on the side walls of the third mask elements of the third mask pattern 140a. The third mask elements of the third mask pattern 140a may then be removed to form the third spacers 240a and 240b.

The third spacers 240a may be formed in the first region A1 and the third spacers 240b may be formed in the second region A2. The third spacers 240a and the third spacers 240b may have equal widths. In the first region A1, the plurality of third spacers 240a may be formed to have predetermined distances between each other. In the second region A2, the plurality of third spacers 240b may be formed to have predetermined distances between each other. A distance between a third spacer 240a and a neighboring third spacer 240a may be different from a distance between a third spacer 240b and a neighboring third spacer 240b. Although the widths of the third spacers 240a and 240b and distances between the third spacers 240a and 240b are described above, the inventive concept is not limited thereto. For example, according to an exemplary embodiment of the inventive concept, widths of the third spacers 240a and 240b and/or distances between the third spacers 240a and 240b may be partially different, entirely different, or may be equal to each other.

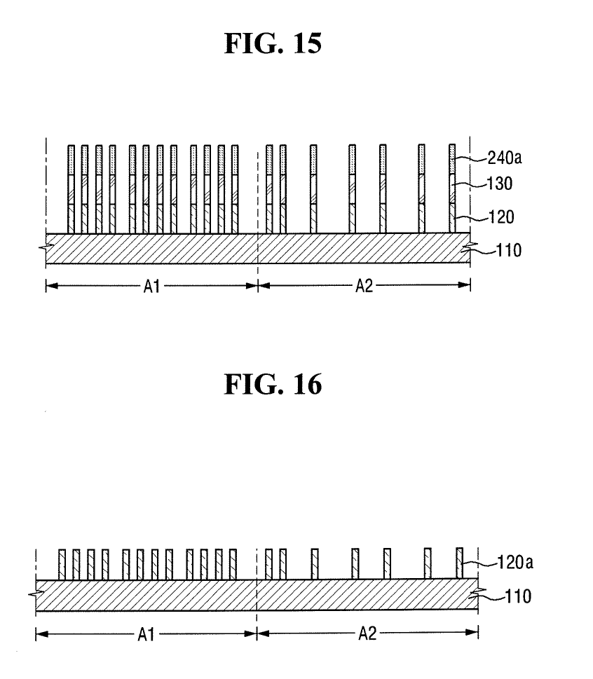

Referring to FIG. 15, the first barrier layer 130 and the first mask layer 120 are sequentially and partially removed. For example, the first barrier layer 130 and the first mask layer 120 may be sequentially and partially removed by an etching process using the third spacers 240a and 240b as masks.

Referring to FIG. 16, the third spacers 240a and 240b and the first barrier layer 130 are removed to form a fourth mask pattern 120a. The fourth mask pattern 120a includes a plurality of fourth mask elements.

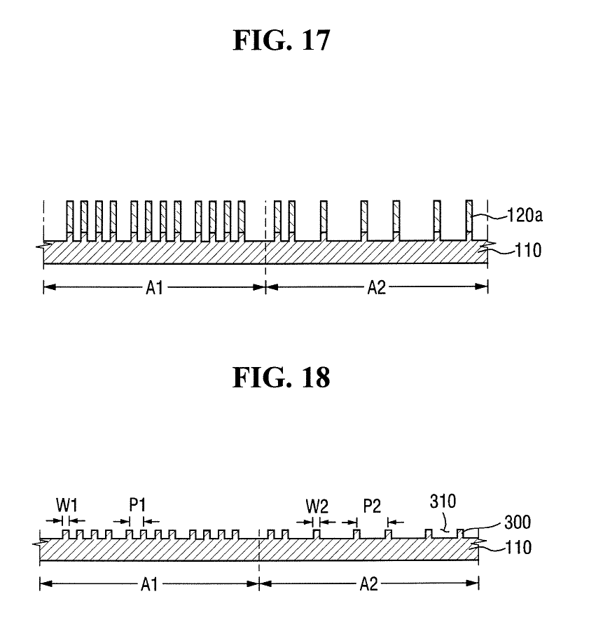

Referring to FIG. 17 and FIG. 18, the substrate 110 may be etched to yield a plurality of fins 300.

For example, the substrate 110 may be etched using the fourth mask elements of the fourth mask pattern 120a as an etching mask to form the plurality of fins 300 and trenches 310 between the fins 300. The fourth mask elements of the fourth mask pattern 120a may be then removed. Accordingly, the substrate 110 with the plurality of fins 300 formed thereon may result as shown in FIG. 18.

Each of the fins 300, formed in the first region A1, may have a first width W1 and may be arranged at a first pitch P1 between a fin 300 and a neighboring fin 300. Each of the fins 300, formed in the second region A2, may have a second width W2 and may be arranged at a second pitch P2 between a fin 300 and a neighboring fin 300. The fins 300 arranged in the same region may have the same width and may be arranged at the same pitch. The first width W1 and the second width W2 may be the same, and the first pitch P1 and the second pitch P2 may be different from each other.

In an exemplary embodiment of the inventive concept, a plurality of fins having different pitches P1 and P2 may be formed in the different regions A1 and A2 of the same substrate 110 without a separate or additional process after the formation of the fins. Thus, the substrate 110 may be patterned in a more simple and stable manner.

In FIG. 18, the substrate 110 includes a single first region A1 and a single second region A2. However, the inventive concept is not limited thereto. For example, in an exemplary embodiment of the inventive concept, the substrate 110 may include a plurality of first regions A1 and a plurality of second regions A2. The plurality of first and second regions A1 and A2 may be formed alternately with each other and may be arranged as needed. It will be apparent that the inventive concept may be applied to a method of forming patterns of a semiconductor device regardless of the quantity or arrangement of regions on a substrate.

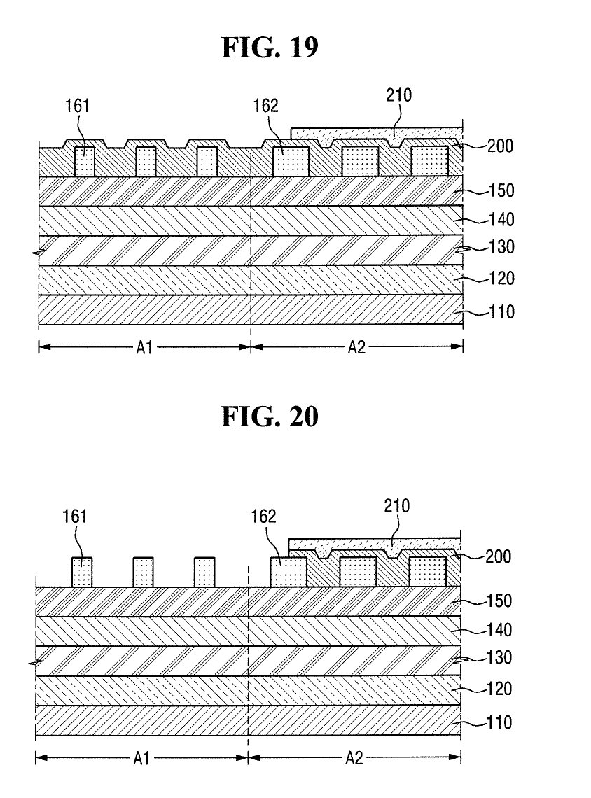

FIG. 19 to FIG. 22 are cross-sectional views illustrating a method of forming patterns of a semiconductor device according to an exemplary embodiment of the inventive concept. In an exemplary embodiment of the inventive concept, the first spacer film 200 fully covers the first and second mask elements of the first and second mask patterns 161 and 162.

Referring to FIG. 19, the first spacer film 200 may fully fill trenches between the first mask elements of the first mask pattern 161 and the second mask elements of the second mask pattern 162. The first spacer film 200 may include an oxide spacer film, for example, a silicon oxide spacer film. The first spacer film 200 may include an oxide layer formed through an ALD or a physical vapor deposition (PVD) process. The first spacer film 200 may include a material that may fully fill trenches between the first mask elements of the first mask pattern 161 and trenches between the second mask elements of the second mask pattern 162. Therefore, any material that may fully fill the trenches between the first mask elements of the first mask pattern 161 and the trenches between the second mask elements of the second mask pattern 162 may be included in the first spacer film 200. A block mask layer 210 may be formed on the first spacer film 200, in the second region A2.

Referring to FIG. 20, the first spacer film 200 may be removed with the exception of the portion of the first spacer film 200 on which the block mask layer 210 is formed.

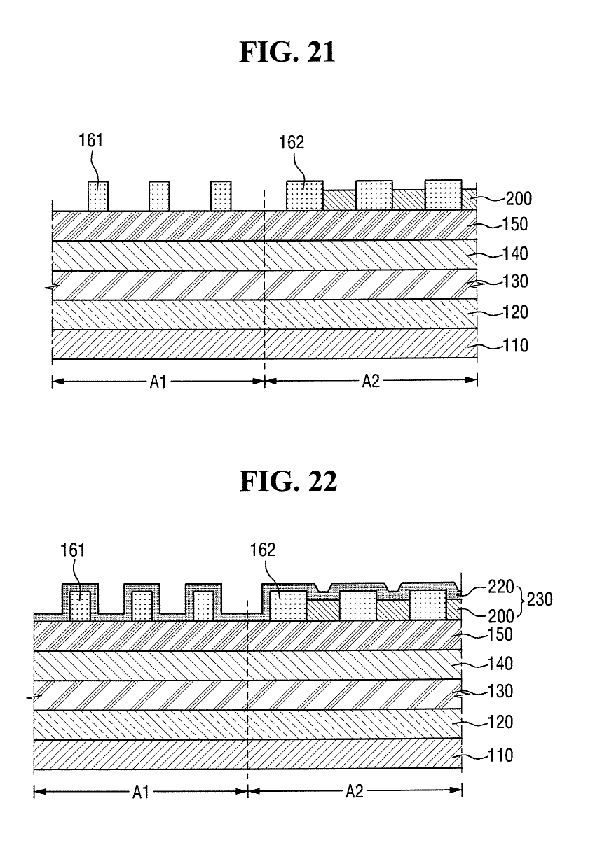

Referring to FIG. 21, the block mask layer 210 may be removed. A portion of the first spacer film 200 may be also removed during the removal of the block mask layer 210. However, the inventive concept is not limited thereto.

Referring to FIG. 22, the second spacer film 220 covers the first region A1 and the second region A2. For example, the second spacer film 220 may be formed on the first spacer film 200 in the second region A2 to fully fill the trenches between the second mask elements of the second mask pattern 162. The first spacer film 200 and the second spacer film 220 may be coupled to form the coupled spacer film 230.

In an exemplary embodiment of the inventive concept, the first spacer film 200 may have a greater thickness than the second spacer film 220. For example, in an exemplary embodiment of the inventive concept, the first spacer film 200 alone may fully fill the trenches between the second mask elements of the second mask pattern 162.

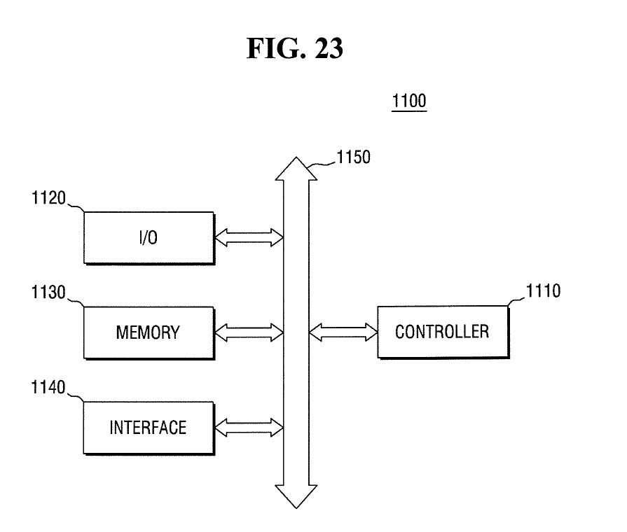

FIG. 23 is a block diagram of an electronic system including a semiconductor device fabricated according to a method of forming patterns of a semiconductor device according to an exemplary embodiment of the inventive concept.

Referring to FIG. 23, an electronic system 1100 may include a controller 1110, an input/output device 1120, a memory device 1130, an interface 1140, and a bus 1150. The controller 1110, the input/output device 1120, the memory device 1130 and/or the interface 1140 may be connected to each other via the bus 1150. Thus bus 1150 serves as a path for data movement.

The controller 1110 may include at least one of a microprocessor, a digital signal processor, a microcontroller, and logic elements capable of performing functions similar to those of the microprocessor, the digital signal processor, and the microcontroller. The input/output device 1120 may include a keypad, a keyboard, a display device, or the like. The memory device 1130 may store data and/or instructions, or the like. The interface 1140 may perform the function of transmitting data to a communication network or receiving data from the communication network. The interface 1140 may be of a wired or wireless type. For example, the interface 1140 may include an antenna or a wired and/or wireless transceiver, or the like.

The electronic system 1110 may further include a high-speed dynamic random access memory (DRAM) and/or static random access memory (SRAM), or the like, serving as an operation memory for enhancing the operation of the controller 1110. For example, a semiconductor device formed according to a method of forming patterns of a semiconductor device according to an exemplary embodiment of the inventive concept may be used as an operation memory component used in the electronic system 1110. Further, the semiconductor device may be provided in the memory device 1130, or may be provided as a component of the controller 1110, the input/output device 1120, or the like.

The electronic system 1100 may be used in a personal digital assistant (PDA), a portable computer, a web tablet, a wireless phone, a mobile phone, a digital music player, a memory card, or any other electronic product capable of transmitting and/or receiving information in a wireless environment.

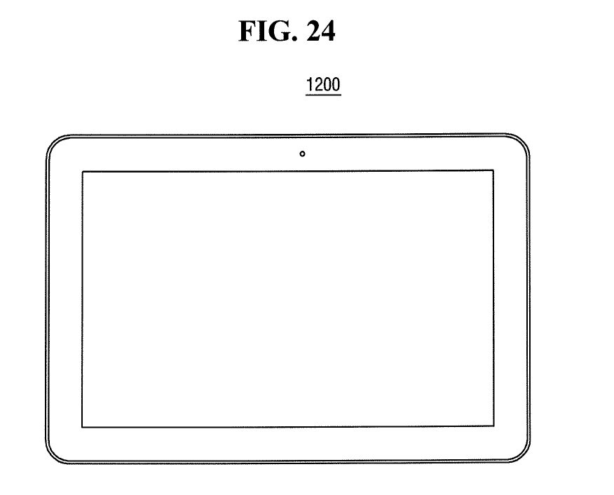

FIG. 24 to FIG. 26 illustrate exemplary semiconductor systems, each of which may use a semiconductor device fabricated according to a method of forming patterns of a semiconductor device according to an exemplary embodiment of the inventive concept.

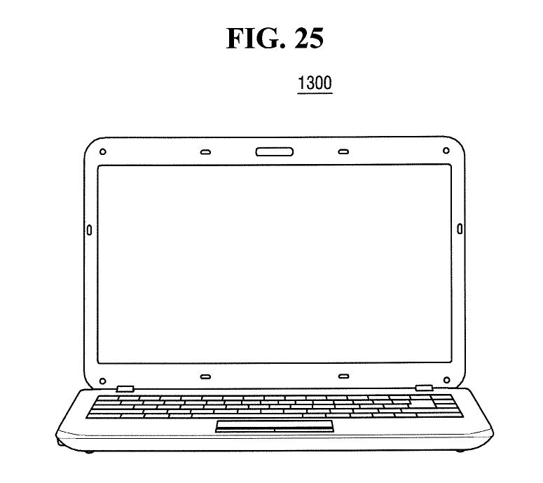

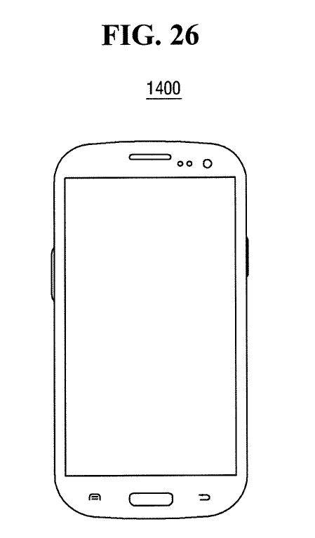

FIG. 24 illustrates a tablet personal computer (PC) 1200, FIG. 25 illustrates a notebook computer 1300, and FIG. 26 illustrates a smartphone 1400. A semiconductor device fabricated according to a method of forming patterns of a semiconductor device according to an exemplary embodiment of the inventive concept may be used in the tablet PC 1200, notebook 1300, smartphone 1400, or the like.

However, it will become apparent to those skilled in the art that a semiconductor device fabricated according to a method of forming patterns of a semiconductor device according to an exemplary embodiment of the inventive concept may be used in integrated circuit devices not illustrated herein. Although only the tablet PC 1200, the notebook computer 1300, and the smartphone 1400 are illustrated above as examples of products using a semiconductor device manufactured according to one or more embodiments of the inventive concept, examples of electronic devices using semiconductor devices fabricated according to exemplary embodiments of the inventive concept are not limited thereto. For example, a semiconductor system fabricated according to an exemplary embodiment of the inventive concept may be used in a computer, an ultra-mobile PC (UMPC), a workstation, a netbook, a PDA, a portable computer, a wireless phone, a mobile phone, an e-book, a portable multimedia player (PMP), a portable game console, a navigation device, a black box, a digital camera, a three-dimensional television, a digital audio recorder, a digital audio player, a digital picture recorder, a digital picture player, a digital video recorder, a digital video player, or the like.

While the inventive concept has been described with reference to exemplary embodiments thereof, it will be understood by those of ordinary skill in the art that various changes in form and detail may be made to the exemplary embodiments.

1. A method of forming patterns of a semiconductor device, comprising:
sequentially forming first to third mask layers on a substrate, wherein the substrate includes a first region and a second region;
etching the third mask layer formed in the first region to form a first mask pattern, wherein the first mask pattern includes a plurality of first mask elements, and etching the third mask layer formed in the second region to form a second mask pattern, wherein the second mask pattern includes a plurality of second mask elements;
forming a first spacer film, wherein the first spacer film covers the second mask elements of the second mask pattern and wherein the first spacer film is not formed in the first region;
forming a second spacer film, the second spacer film being disposed on the first spacer film to fully fill at least one trench between the second mask elements of the second mask pattern and being disposed on the first mask elements of the first mask pattern;
removing portions of the first and second spacer films covering upper surfaces of the first and second mask elements of the first and second mask patterns to expose the upper surfaces of the first and second mask elements of the first and second mask patterns;
etching the second mask layer to form a third mask pattern, wherein the third mask pattern includes a plurality of third mask elements;
etching the first mask layer using the third mask elements of the third mask pattern to form a fourth mask pattern, wherein the fourth mask pattern includes a plurality of fourth mask elements; and
etching the substrate using the fourth mask elements of the fourth mask pattern.

2. The method of claim 1, wherein forming the first spacer film comprises conformally covering at least one second mask element of the second mask pattern.

3. The method of claim 1, wherein the first mask layer comprises two layers.

4. The method of claim 1, wherein forming the first spacer film comprises forming the first spacer film covering the first mask elements of the first mask pattern and the second mask elements of the second mask pattern, forming a block mask layer in the second region to at least partially cover the first spacer film, and removing the first spacer film disposed in the first region.

5. The method of claim 1, wherein a first distance between neighboring second mask elements of the second mask pattern is equal to or less than double a sum of a thickness of the first spacer film and a thickness of the second spacer film.

6. The method of claim 1, wherein a first pitch of a first mask element, from among the plurality of first mask elements of the first mask pattern, and a second pitch of a second mask element, from among the plurality of the second mask elements of the second mask pattern, are equal.

7. The method of claim 1, wherein a first mask element, from among the plurality of first mask elements of the first mask pattern, has a first width, and a second mask element, from among the plurality of second mask elements of the second mask pattern, has a second width, and wherein the first width and the second width are not equal.

8. The method of claim 1, wherein a thickness of the first spacer film is greater than a thickness of the second spacer film.

9. The method of claim 1, wherein etching the substrate comprises forming a plurality of fins, wherein a first distance between neighboring fins from among the plurality of fins formed in the first region is shorter than a second distance between neighboring fins from among the plurality of fins formed in the second region.

10. A method of forming patterns of a semiconductor device, comprising:
forming a mask layer on a target layer, wherein the target layer includes a first region and a second region;
etching the mask layer formed in the first region to form a first mask pattern, wherein the first mask pattern includes a plurality of first mask elements, wherein at least one first mask element of the first mask pattern has a first width, and wherein the at least one first mask element of the first mask pattern is spaced apart from a proximate first mask element of the first mask pattern by a first distance;
etching the mask layer formed in the second region to form a second mask pattern, wherein the second mask pattern includes a plurality of second mask elements, wherein at least one second mask element has a second width, wherein the second width and the first width are not equal, and wherein the at least one second mask element of the second mask pattern is spaced apart from a proximate second mask element of the second mask pattern by a second distance;
forming a first spacer film, wherein the first spacer film covers the second mask elements of the second mask pattern, and wherein the first spacer film is not formed in the first region;
forming a second spacer film, wherein the second spacer film is disposed on the first spacer film to fully fill at least one trench between the second mask elements of the second mask pattern, and wherein the second spacer film covers the first mask elements of the first mask pattern;
removing portions of the first and second spacer films covering upper surfaces of the first and second mask elements of the first and second mask patterns to expose the upper surfaces of the first and second mask elements of the first and second mask patterns; and
etching the target layer.

11. The method of claim 10, wherein a thickness of the first spacer film is greater than a thickness of the second spacer film.

12. The method of claim 10, wherein the second distance between the at least one second mask element of the second mask pattern and the proximate second mask element of the second mask pattern is equal to or less than double a sum of a thickness of the first spacer film and a thickness of the second spacer film.

13. The method of claim 10, wherein a first pitch of a first mask element, from among the plurality of first mask elements of the first mask pattern, and a second pitch of a second mask element, from among the plurality of second mask elements of the second mask pattern, are equal.

14. A method of forming patterns of a semiconductor device, comprising:
sequentially forming first to third mask layers on a substrate, wherein the substrate includes a first region and a second region;
etching the third mask layer formed in the first region to form a first mask pattern, wherein the first mask pattern includes a plurality of first mask elements, and etching the third mask layer formed in the second region to form a second mask pattern, wherein the second mask pattern includes a plurality of second mask elements;
forming a first spacer film, wherein the first spacer film covers the second mask elements of the second mask pattern and wherein the first spacer film is not formed in the first region;
forming a second spacer film, wherein the second spacer film is disposed on the first spacer film, wherein the second spacer film fully fills at least one trench between the second mask elements of the second mask pattern, wherein the second spacer film is disposed on the first mask elements of the first mask pattern;
removing portions of the first spacer film and portions of the second spacer film to expose upper surfaces of the first mask elements of the first mask pattern and upper surfaces of the second mask elements of the second mask pattern;
etching the second mask layer to form a third mask pattern, wherein the third mask pattern includes a plurality of third mask elements;
forming a third spacer film, wherein the third spacer film covers the third mask elements of the third mask pattern;
removing portions of the third spacer film to expose upper surfaces of the third mask elements of the third mask pattern;
etching the first mask layer to form a fourth mask pattern, wherein the fourth mask pattern includes a plurality of fourth mask elements; and
etching the substrate to form a plurality of fins.

15. The method of claim 14, wherein at least one distance between adjacent second mask elements of the second mask pattern is equal to or less than double a sum of a thickness of the first spacer film and a thickness of the second spacer film.

16. The method of claim 14, wherein at least one pitch of a fin formed in the first region is different from at least one pitch of a fin formed in the second region.

17. The method of claim 14, wherein forming the first spacer film comprises conformally covering at least one second mask element of the second mask pattern.

18. The method of claim 14, wherein the first mask layer comprises two layers.

19. The method of claim 14, wherein forming the first spacer film comprises forming the first spacer film covering the first mask elements of the first mask pattern and the second mask elements of the second mask pattern, forming a block mask layer in the second region to cover the first spacer film, and removing the first spacer film disposed in the first region.

20. The method of claim 14, wherein a thickness of the first spacer film is greater than a thickness of the second spacer film.

21. The method of claim 14, wherein a first mask element, from among the plurality of first mask elements of the first mask pattern, has a first width, and a second mask element, from among the plurality of second mask elements of the second mask pattern has a second width, and wherein the first width and the second width are not equal.

22. The method of claim 14, wherein a first pitch of a first fin, from among the plurality of fins in the first region, is equal to a second pitch of a second fin, from among the plurality of fins in the second region.

23. The method of claim 14, wherein forming the third spacer film comprises conformally covering at least one third mask element of the third mask pattern.
